(19) United States
(12) Patent Application Publication
(10) Pub. No.: US 2017/0069358 A1
(43) Pub. Date: Mar. 9, 2017

(54) MEMORY DEVICE AND METHOD OF OPERATION THEREOF

(71) Applicant: SK hynix Inc., Gyeonggi-do (KR)

(72) Inventors: Tae-Sik YUN, Gyeonggi-do (KR); Jae-Jin LEE, Gyeonggi-do (KR)

(21) Appl. No.: 15/046,090

(22) Filed: Feb. 17, 2016

(30) Foreign Application Priority Data
Sep. 8, 2015 (KR) 10-2015-0127080

(51) Int. Cl. G11C 7/06; G11C 7/12

(52) U.S. Cl. CPC G11C 7/062; G11C 7/12

(57) ABSTRACT

An operation method of a memory device may include writing first data to a plurality of memory cells corresponding to a plurality of word lines, enabling a sense amplifier corresponding to the memory cells and setting second data in the sense amplifier, the second data having the opposite phase of the first data, and sequentially enabling the plurality of word lines for a predetermined time while enabling the sense amplifier.

### CROSS-REFERENCE TO RELATED APPLICATIONS

The present application claims priority of Korean Patent Application No. 10-2015-0127080, filed on Sep. 8, 2015, which is incorporated herein by reference in its entirety.

### BACKGROUND

1. Field

The present disclosure relates generally to semiconductor technology and more particularly to a memory device.

2. Description of the Related Art

Memory devices are required to operate at high speed. A write recovery time tWR is one parameter of a memory device that controls its overall operation performance. Specifically, a write recovery time of a memory device indicates the time it takes from the point of starting to perform a write operation for storing data in a memory cell of the memory device to the point of starting a subsequent precharge operation that does not affect the stored data. Hence, a write recovery time is the minimum time required to elapse for properly storing data in a memory cell of the memory device from the point where a write command is applied to the memory device. Thus, a memory controller should apply a precharge command to the memory device after a time equal to or greater than the write recovery time has elapsed from the point where the write command is applied to the memory device.

Generally, miniaturization of memory devices increases the contact resistance of memory cells included therein which in turn increases their write recovery time. Hence, as memory devices become smaller, demand for technologies which more accurately and rapidly measure the write recovery time of memory devices increases.

### SUMMARY

Various embodiments are directed to a technology for rapidly and accurately measuring a write recovery time of a memory device.

In an embodiment, an operation method of a memory device may include writing a first datum (a data bit) to each of a plurality of memory cells corresponding to a plurality of word lines, wherein the first datum is written to each of the memory cells coupled to a bit line of a bit line pair while the complement of the first datum is written to each of the memory cells coupled to a complement bit line of the bit line pair, enabling a sense amplifier corresponding to the memory cells and loading a second datum, the second datum from a data bus that is coupled to the bit line pair via an I/O switch, into the sense amplifier meaning that the sense amplifier senses and amplifies the second datum such that the amplifier drives the bit line and the complement bit line with the second datum and the complement of the second datum, respectively, the second datum being the complement of the first datum, and sequentially enabling the plurality of word lines each enabled for a predetermined time while enabling the sense amplifier.

The operation method may further include checking whether write recovery times (tWR) of the memory cells are a pass or a fail, through read operations for the memory cells.

In the enabling of the plurality of word lines each for the predetermined time, the word lines may be activated one at a time, or two or more of the word lines may be activated at a time for the predetermined time.

The loading of the second datum into the sense amplifier may be performed in a state where all of the word lines are disabled.

In an embodiment, a memory device may include a plurality of word lines, a plurality of memory cells corresponding to the word lines, a sense amplifier suitable for amplifying a datum of a memory cell corresponding to an enabled word line among the plurality of word lines, and the sense amplifier maintaining an active state while being loaded with a second datum in a test mode, and a test circuit suitable for controlling the plurality of word lines to be sequentially enabled each for a predetermined time, in the test mode.

In the test mode, a second datum being a complement of the first datum may be written to each of the plurality of memory cells.

The word lines may be enabled one at a time in a state where the sense amplifier may be enabled in the test mode. Furthermore, two or more of the word lines may be enabled at a time in a state where the sense amplifier may be enabled in the test mode.

The memory device may further include a row circuit suitable for controlling the plurality of word lines. The row circuit may control the plurality of word lines in response to an external active command, an external precharge command, and an external row address which are applied from outside the memory device in a normal mode, and control the plurality of word lines in response to an internal active command, an internal precharge command, and an internal row address which are generated through the test circuit, in the test mode.

The memory device may further include a sense amplifier control circuit suitable for controlling the sense amplifier. The sense amplifier control circuit may enable/disable the sense amplifier in response to the external active command and the external precharge command in the normal mode, and control the sense amplifier to maintain the active state in the test mode.

The memory device may further include a data control circuit suitable for controlling data exchange between the sense amplifier and the data bus. The data control circuit may control the data exchange between the sense amplifier and the data bus in response to an external read command, an external write command, and an external column address which are applied from outside the memory device in the normal mode, and apply the second datum from the data bus to the sense amplifier in the test mode.

In the test mode, all of the word lines may be disabled at the point of time that the sense amplifier starts to be enabled.

In an embodiment, an operation method of a memory device may include writing a first datum to each of a plurality of memory cells disposed at respective intersections between a plurality of word lines and a plurality of bit lines, transmitting and loading data second datum to/on the bit lines while disabling the word lines, sequentially enabling the word lines each for a predetermined time while continuing to load the second datum on the bit lines, and checking whether each of the plurality of memory cells has the first datum or the second datum through read operations thereof.

### BRIEF DESCRIPTION OF THE DRAWINGS

FIG. 1 is a diagram illustrating memory cells, bit lines, word lines, a sense amplifier, and an I/O switch of a memory device, according to an embodiment of the present invention.

FIG. 2 is a flowchart illustrating an example of an operation method for measuring a write recovery time tWR of a memory device, according to an embodiment of the present invention.

FIG. 3 is a timing diagram corresponding to the flowchart of FIG. 2.

FIG. 4 is a flowchart illustrating an example of an operation method for measuring a write recovery time tWR of the memory device, according to another embodiment of the present invention.

FIG. 5 is a timing diagram corresponding to the flowchart of FIG. 4.

FIG. 6 is a configuration diagram of a memory device which operates as illustrated in FIGS. 4 and 5, according to an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the present invention to those skilled in the art. Throughout the disclosure, like reference numerals refer to like parts throughout the various figures and embodiments of the present invention.

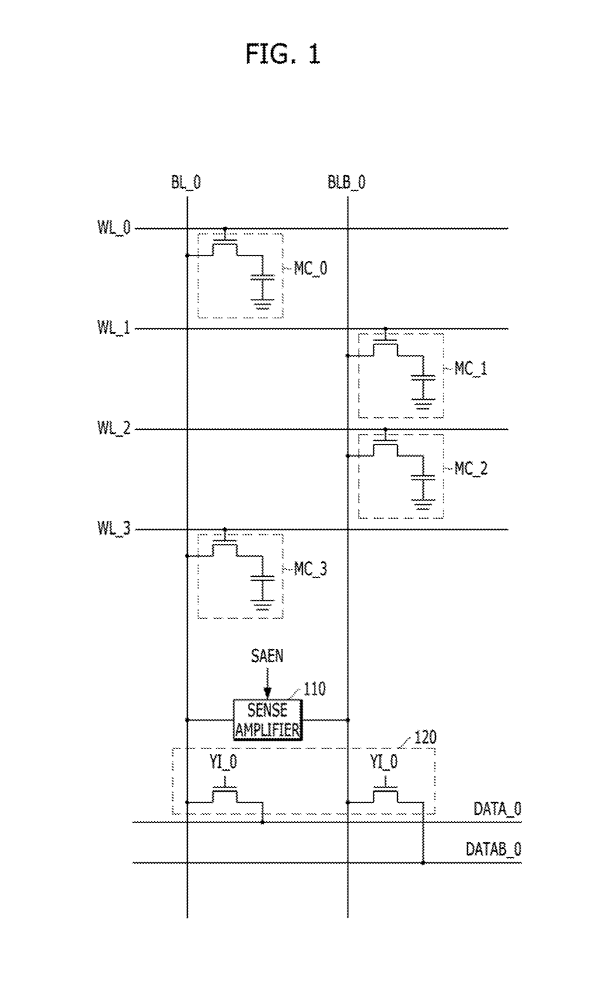

Referring to FIG. 1, a memory device according to an embodiment of the present invention is provided. Accordingly, the memory device may include a plurality of word lines WL_0 to WL_3 extending in a row direction, and a plurality of bit lines BL_0 and BLB_0 extending in a column direction. Although only four word lines and 2 bit lines are shown in the embodiment of FIG.1, it is noted that any suitable number of word lines and bit lines may be employed.

A plurality of memory cells, for example, memory cells MC_0 to MC_3 may be formed at the respective intersections between the word lines WL_0 to WL_3 and the bit lines BL_0 and BLB_0. Each of the memory cells MC_0 to MC_3 may include a capacitor and a transistor. Each capacitor may store a datum (a bit of data) while each transistor may control the electrical coupling between the capacitor and a corresponding bit line under the control of a corresponding word line. For example, the transistor of the memory cell MC_1 may control the electrical coupling between the capacitor of the memory cell MC_1 and the bit line BLB_0 under the control of the word line WL_1.

A sense amplifier 110 may be electrically coupled to the bit lines BL_0 and BLB_0. The sense amplifier SAEN 110 may be enabled in response to an enable signal SAEN, and amplify a voltage difference between the bit lines BL_0 and BLB_0. Through the amplification operation of the sense amplifier 110, a datum of a memory cell selected among the memory cells MC0 to MC3 may be read or a datum may be written to the selected memory cell.

The I/O switch 120 may electrically couple the bit lines BL_0 and BLB_0 to data buses DATA_0 and DATAB_0, respectively, when a column select signal YI_0 is activated. For example, for a read operation, data may be transmitted from the bit lines BL_0 and BLB_0 to the data buses DATA_0 and DATAB_0. For a write operation, data may be transmitted from the data buses DATA_0 and DATAB_0 to the bit lines BL_0 and BLB_0.

For simplicity of description, FIG. 1 illustrates four word lines WL_0 to WL_3, the pair of bit lines BL_0 and BLB_0, the four memory cells MC_0 to MC_3, the one sense amplifier 110, and the one I/O switch 120. However, an actual memory device may include larger numbers of word lines, bit line pairs, memory cells, sense amplifiers, and I/O switches.

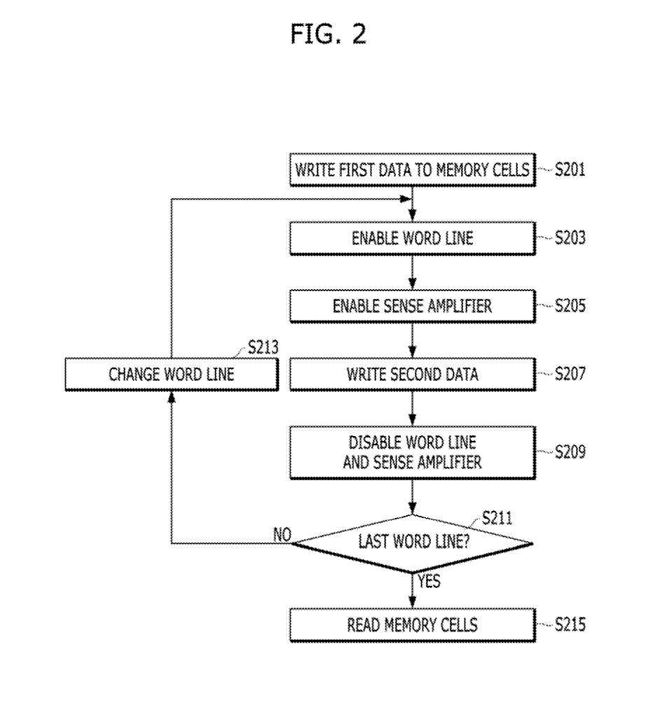

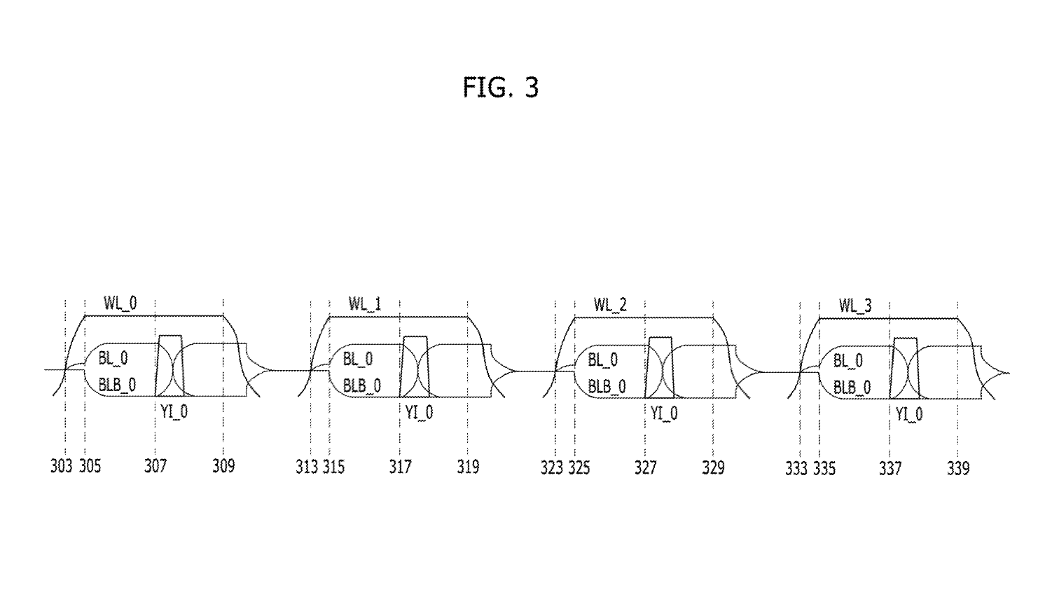

FIG. 2 is a flowchart illustrating an example of an operation method for measuring a write recovery time tWR of a memory device. FIG. 3 is a timing diagram corresponding to the flowchart of FIG. 2.

Referring to FIG. 2, the same first data may be written to the memory cells MC_0 to MC_3 of the memory device, and the same datum, the complement of the first datum, may be written to each of the memory cells MC_1 and MC_2 of the memory device at step S201. For example, the first datum may be ‘1’ written through the bit line BL_0 and its complement ‘0’ may be written through the bit line BLB_0. The same first datum may be written to each of the memory cells MC_0 and MC_3, and the same datum, the complement of the first datum, may be written to each of the memory cells MC_1 and MC_2 through several normal write operations. Alternatively, the first datum may be written through a method which is used to write the same datum to each of all memory cells during a test referred to also as a parallel test or a compression test.

Then, the first word line WL_0 corresponding to the first memory cell MC_0 may be enabled to transmit the datum of the first memory cell MC_0 to the bit line BL_0 at step S203. FIG. 3 shows that the first word line WL_0 may be enabled at a time 303, and the first datum stored in the first memory cell MC_0 may be transmitted to the bit line BL_0 (this process is referred to as charge sharing), such that the voltage level of the bit line BL_0 may become higher than the voltage level of the bit line BLB_0.

After the charge sharing between the first memory cell MC_0 and the bit line BL_0, the sense amplifier 110 may be enabled to amplify the sensed voltage difference between the bit line pair BL_0 and BLB_0 at step S205. FIG. 3 shows that the sense amplifier 110 may be enabled at a time 305 and may amplify the voltage difference between the bit line pair BL_0 and BLB_0.

After the sense amplifier 110 is enabled, the column select signal YI_0 may be activated to perform a write operation of transmitting a second datum and its complement from the data buses DATA_0 and DATAB_0 to the bit line pair BL_0 and BLB_0, at step S207. The second datum may be ‘0’ transmitted to the bit line BL_0 and its complement may be ‘1’ transmitted to the bit line BLB_0. FIG. 3 shows that the column select signal YI_0 is activated at a time 307 and the data loaded in the bit line BL_0 and BLB_0 is changed according to the second datum and its complement. Since the first word line WL_0 is enabled, the second datum loaded in the bit line pair BL_0 and BLB_0 may be written to the first memory cell MC_0.

Then, the first word line WL_0 may be disabled, and the sense amplifier 110 may be disabled, at step S209. At step S211, a determination is made as to whether or not the word line being processed is the last word line. If the word line being processed is the last word line then memory cells are read at step S215 otherwise the word line is changed to a different word line at step S213. FIG. 3 shows that at a time 309 the first word line WL_0 is disabled and the sense amplifier 110 is disabled to precharge the bit line pair BL_0 and BLB_0 to the same voltage level. As the first word line WL_0 is disabled, the write operation of the first memory cell MC_0 may be ended. Thus, the write operation of the first memory cell MC_0 may be performed during a time period from the time 307 that the column select signal YI_0 is activated to the time 309 that the first word line is disabled. When a write operation is properly performed in a short time period between the times 307 and 309, the first memory cell MC_0 may be considered as having satisfactory tWR characteristics. When a write operation is properly performed in a long time period between the times 307 and 309, the first memory cell MC_0 may be considered as having unsatisfactory tWR characteristics. Therefore, the time period between the times 307 and 309 may be set to a value corresponding to the target tWR of the first memory cell MC_0.

So far, the operation of writing the second data for testing the write recovery time tWR of the first memory cell MC_0 corresponding to the first word line WL_0 has been described. In order to test the write recovery times tWR of the memory cells MC_1 to MC_3 corresponding to the word lines WL_1 to WL3, steps S203 to S209 may be repeated for a number of times that is equal to the word lines. For example, as shown in FIG. 3, times 313 to 339 may represent write operations for testing the write recovery times tWR of the memory cells MC_1 to MC_3 corresponding to the word lines WL_1 to WL3.

After the second datum has been written to each of the memory cells MC_0 and MC_3 corresponding to the word lines WL_1 and WL3, and the complement of the second datum has been written to each of the memory cells MC_1 and MC_2 corresponding to word lines WL_1 and WL_2, read operations for the memory cells MC_0 to MC_3 may be performed at step S215. Read operations may be performed separately for each of the memory cells MC_0 to MC_3. For example, four read operations one for each of the memory cells MC_0 to MC_3 may be performed. When the second datum is read as a result of a read operation for MC_0 or MC_3, or its complement is read as a result of a read operation for MC_1 or MC_2, it may indicate that the corresponding memory cell satisfies the tWR target value. When the second datum is not read from MC_0 or MC_3, or its complement from MC_1 or MC_2, it may indicate that the corresponding memory cell does not satisfy the tWR target value. For example, when the second datum is read from each of the memory cells MC_0 and MC_3, and its complement is read from MC_2, but the complement of first datum is read from the memory cell MC_1, then the memory cells MC_0, MC_2, and MC3 may be a tWR pass, while the memory cell MC_1 may be a tWR fail.

The tWR test method illustrated in FIGS. 2 and 3, may thus include enabling a word line, enabling a sense amplifier 110, performing a write operation including activating the column select signal YI_0 to write the second datum, and performing a precharge operation including disabling the word line and the sense amplifier 110, in order to write the second datum to a memory cell corresponding to the word line WL_0 or WL_3, or to write the complement of the second datum to a memory cell corresponding to the word line WL_1 or WL_2. A memory device may include from several hundreds to several thousands of word lines, hence the time needed for the tWR test may be controlled by the number of the word lines.

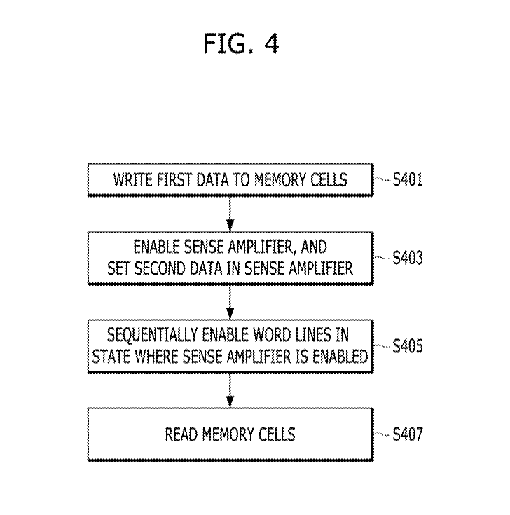

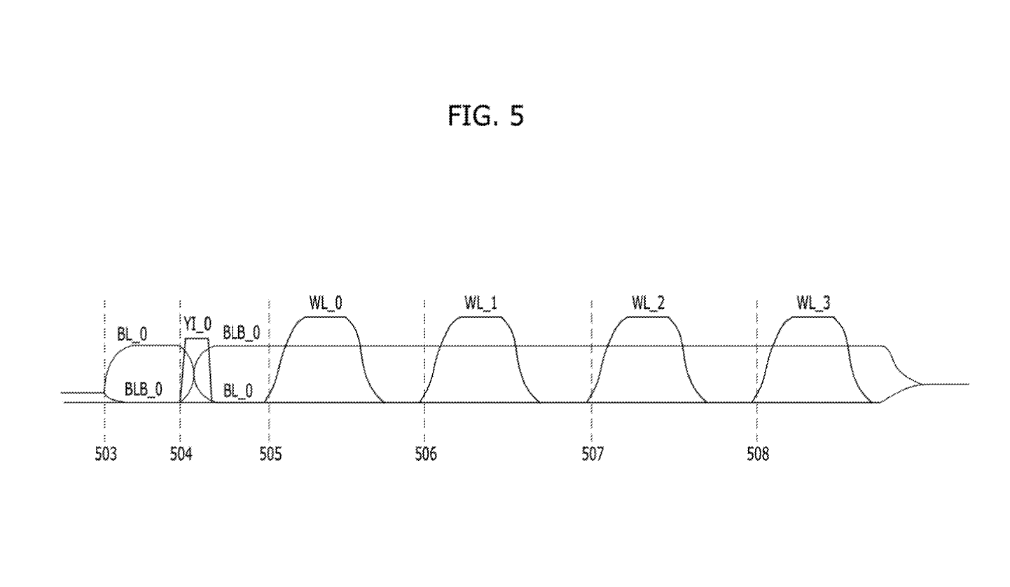

FIG. 4 is a flowchart illustrating another example of an operation method for measuring a write recovery time tWR of a memory device that is generally more time efficient than the one described above with regard to FIGS. 2 and 3. FIG. 5 is a timing diagram corresponding to the flowchart of FIG. 4.

Referring to FIG. 4, the same first datum may be written to each of the memory cells MC_0 and MC_3 of the memory device, and the same datum, the complement of the first datum, may be written to each of the memory cells MC_1 and MC_2, at step S401. For example, the first datum may be ‘1’ written through the bit line BL_0 and its complement ‘0’ may be written through the bit line BLB_0. The same first datum, the complement of the first datum, may be written to each of the memory cells MC_1 and MC_2 may be written to the memory cells MC_0 to MC_3 through several normal write operations. Alternatively, the first datum may be written through a method which is used to write the same datum to each of all memory cells during a test known as a parallel test or a compression test.

Then, while data according to first datum are still loaded on the bit line pair, the sense amplifier 110 may be enabled to load a second datum in the sense amplifier 110, the second datum being a complement of the first datum, at step S403. The second datum ‘0’ is written through the bit line BL_0 and its complement ‘1’ is written through the bit line BLB_0. FIG. 5 shows that the sense amplifier 110 may be enabled at a time 503, and may amplify a voltage difference between the bit line pair BL_0 and BLB_0. FIG. 5 illustrates that the bit line pair BL_0 and BLB_0 has data in accordance with the first datum. However, since no word lines are enabled at the time 503, the bit line pair BL_0 and BLB_0 may receive data corresponding to the second datum. At a time 504, the column select signal YI_0 may be activated to transmit the second data of the data buses DATA_0 and DATA_B_0 corresponding to the second datum to the bit line pair BL_0 and BLB_0, and the sense amplifier 110 may amplify the data. That is, the state in which the sense amplifier 110 may be enabled to amplify the second datum may be maintained.

Then, the word lines WL_0 to WL_3 may be sequentially enabled each for a predetermined time, in a state where the sense amplifier 110 is enabled, at step S405. FIG. 5 shows that the first word line WL_0 may be enabled at a time 505 and disabled after a predetermined time. During the active period of the first word line WL_0, the second datum may be written to the first memory cell MC_0. That is, the active period of the first word line WL_0 may correspond to the write operation period of the first memory cell MC_0. At a time 506, the second word line WL_1 may be enabled and then disabled after a predetermined time. The active period of the second word line WL_1 may correspond to the write operation period (the write recovery time) of the second memory cell MC_1. At a time 507, the third word line WL_2 may be enabled and then disabled after a predetermined time. At a time 508, the fourth word line WL_3 may be enabled and then disabled after a predetermined time. During the active period of the third word line WL_2, the second datum may be written to the third memory cell MC_2, and during the active period of the fourth word line WL_3, the second datum may be written to the fourth memory cell MC_3. The active periods of the word lines WL_0 to WL_3 may determine the write operation periods of the memory cells MC_0 to MC_3. Thus, among the memory cells MC_0 to MC_3, memory cells that have a write operation properly performed in the short active periods of the word lines WL_0 to WL_3 may be considered as having satisfactory tWR characteristics, and memory cells that have a write operation properly performed only in the long active periods of the word lines WL_0 to WL_3 may be considered as having unsatisfactory tWR characteristics. Thus, the lengths of the active periods of the word lines WL_0 to WL_3 may be set to values corresponding to the target write recovery times tWR of the memory cells MC_0 to MC_3.

After the word lines WL_1 to WL3 are sequentially enabled, that is, after the second datum has been attempted to be written to the memory cells MC_0 and MC_3, and the complement of the second datum has been attempted to be written to each of memory cells MC_1 and MC_2, read operations for the memory cells MC_0 to MC_3 may be performed at step S407. Read operations may be performed separately for each of the memory cells MC_0 to MC_3. For example, four read operations corresponding to the number of the memory cells MC_0 to MC_3 may be performed. When the second datum is read or a datum corresponding to the second datum is read as the result of a read operation, it may indicate that the corresponding memory cell satisfies the tWR target value. When the second datum or a datum corresponding to the second datum is not read, it may indicate that the corresponding memory cell does not satisfy the tWR target value. For example, when the second datum is read from the memory cells MC_0 and MC_3, and its complement is read from MC_2, but the complement of first datum is read from the memory cell MC_1, the memory cells MC_0, MC_2, and MC3 may be a tWR pass, while the memory cell MC_1 may be a tWR fail.

Referring to FIGS. 4 and 5, the operation of writing the second datum or a datum corresponding to the second datum being driven on the true bit line of the bit line pair to each of the memory cells MC_0 to MC_3 may be performed only by sequentially enabling the word lines WL_0 to WL_3 in a state where the second datum is loaded in the sense amplifier 110. Thus, the operation time for measuring the write recovery time of the memory device may be reduced.

FIG. 5 illustrates that the word lines WL_0 to WL_3 are enabled one at a time. However, two or more of the word lines may be enabled each time. For example, after the word lines WL_0 and WL_2 are enabled at the same time and then disabled, the word lines WL_1 and WL_3 may be enabled at the same time and then disabled. In this case, the second data write operations for the memory cells

MC_0 and MC_2 may be performed at the same time, and the second data write operations for the memory cells MC_1 and MC_3 may be performed at the same time.

In the described embodiment, the first datum may correspond to the bit line BL_0 having value ‘1’ and the bit line BLB_0 having value ‘0’, and the second datum may correspond to the bit line BL_0 having value ‘0’ and the bit line BLB_0 having value ‘1’. However, the first datum may correspond to the bit line BL_0 having value ‘0’ and the bit line BLB_0 having value ‘1’, and the second datum may correspond to the bit line BL_0 having value ‘1’ and the bit line BLB_0 having value ‘0’. That is, the first datum and the second datum may each be the complement of the other.

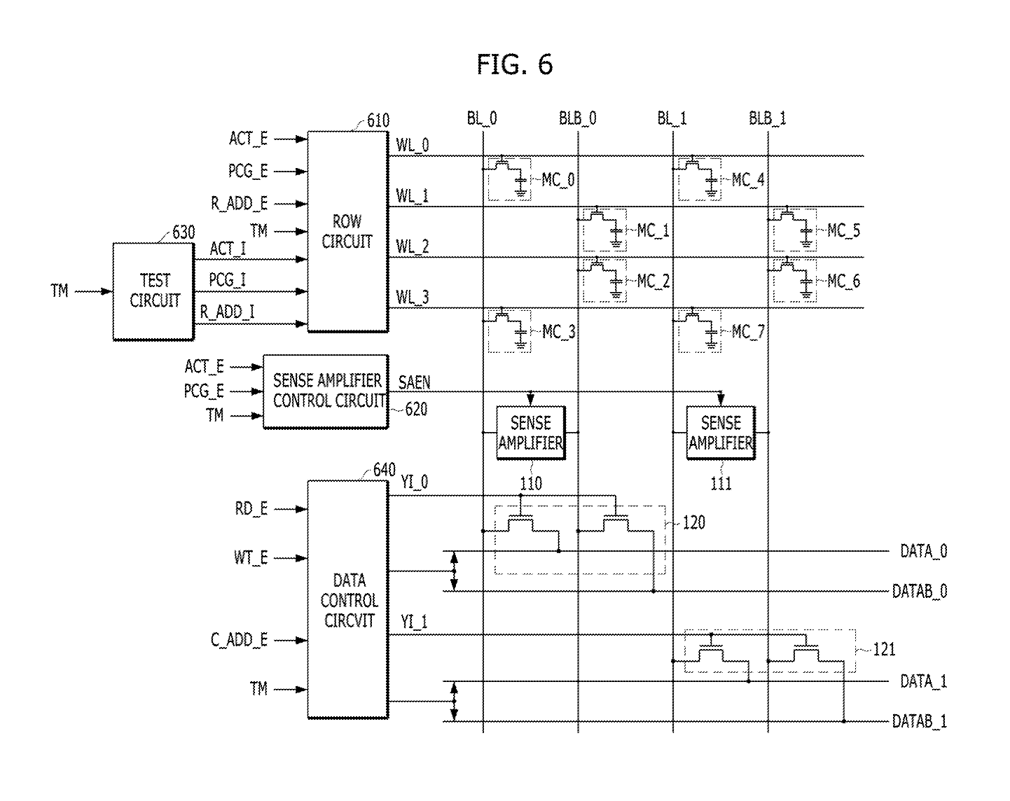

FIG. 6 is a configuration diagram of a memory device which may operate as illustrated in FIGS. 4 and 5, according to an embodiment of the invention.

Referring to FIG. 6, the memory device may include word lines WL_0 to WL_3, bit lines BL_0, BLB_0, BL_1, and BLB_1, memory cells MC_0 to MC_7, sense amplifiers 110 and 111, I/O switches 120 and 121, a row circuit 610, a sense amplifier control circuit 620, a data control circuit 640, and a test circuit 630.

The test circuit 630, which is configured for the operation S405 of FIG. 4, may be enabled in a test mode when a test mode signal TM is activated. The test mode signal TM may be activated during the operation S405 for writing the second data to the memory cells. The test circuit 630 may be enabled to generate an internal active command ACT_I, an internal precharge command PCG_I, and an internal row address R_ADD_I. The internal row address R_ADD_I may indicate an address for selecting one of the word lines WL_0 to WL_3. The internal active command ACT_I may indicate a signal for enabling a selected word line. The internal precharge command PCG_I may indicate a signal for disabling an enabled word line. The test circuit 630 may generate the internal active command ACT_I, the internal precharge command PCG_I, and the internal row address R_ADD_I such that the word lines WL_0 to WL_3 are sequentially enabled at the operation S405 of FIG. 4 and the times 505 to 508 of FIG. 5.

In a normal mode in which the test mode signal TM may be deactivated, the row circuit 610 may control the word lines WL_0 to WL_3 in response to an external active command ACT_E, an external precharge command PCG_E, and/or an external row address R_ADD_E. The external active command ACT_E, the external precharge command PCG_E, and/or the external row address R_ADD_E may be inputted from a device external to the memory device. The row circuit 610 may select a word line to be enabled among the word lines WL_0 to WL_3, using the external row address R_ADD_E. Furthermore, the row circuit 610 may enable the selected word line in response to the external active command ACT_E, and disable the enabled word line in response to the external precharge command PCG_E. In the test mode in which the test mode signal TM is activated, the row circuit 610 may control the word lines WL_0 to WL_3 in response to the internal active command ACT_I, the internal precharge command PCG_I, and/or the internal row address R_ADD_I, instead of the external active command ACT_E, the external precharge command PCG_E, and the external row address R_ADD_E.

The sense amplifier control circuit 620 may control an operation of enabling or disabling the sense amplifiers 110 and 111. In a normal mode in which the test mode signal TM may deactivated, the sense amplifier control circuit 620 may activate the sense amplifier enable signal SAEN in response to the external active command ACT_E, and deactivate the sense amplifier enable signal SAEN in response to the external precharge command PCG_E. Furthermore, in a test mode in which the test mode signal TM may be activated, the sense amplifier control circuit 620 may continuously maintain the sense amplifier enable signal SAEN in an active state. Thus, during the operation S405 of FIG. 4 and the times 505 to 508 of FIG. 5, the sense amplifiers 110 and 111 may continuously maintain the active state.

The data control circuit 640 may control data exchange between the sense amplifiers 110 and 111 (or the bit line pairs BL_0/BLB_0 and BL_1/BLB_1) and data buses DATA_0/DATAB_0 and DATA_1/DATAB_1. In a normal mode in which the test mode signal TM may be deactivated, the data control circuit 640 may control the data exchange between the sense amplifiers 110 and 111 and the data buses DATA_0/DATAB_0 and DATA_1/DATAB_1 in response to an external read command RD_E, an external write command WT_E, and an external column address C_ADD_E which are inputted from outside the memory device. The data control circuit 640 may generate column select signals YI_0 and YI_1 such that a column selected by the external column address C_ADD_E can be coupled to the data bus DATA_0/DATAB_0 or DATA_1/DATAB_1 during a read or write operation. In the test mode in which the test mode signal TM is activated, the data control circuit 640 may apply the second data to the data buses DATA_0/DATAB_0 and DATA_1/DATAB_1 and activate the column select signals YI_0 and YI_1 to set the second data in the sense amplifiers 110 and 111.

The memory device having the configuration illustrated in FIG. 6 may be operated as illustrated in FIGS. 4 and 5, when measuring the write recovery time tWR. Thus, the memory device may more rapidly and accurately measure the write recovery time tWR.

FIGS. 1 to 6 illustrate that the cell array has a folded bit line structure. However, this is only an example, and the cell array may have an open bit line structure.

According to various embodiments of the present invention, a memory device and a method of operation thereof are provided for measuring a write recovery time of the memory device more rapidly and/or accurately.

Although various embodiments of the invention have been described for illustrative purposes, it will be apparent to those skilled in the art that various changes and modifications may be made without departing from the spirit and scope of the invention as defined in the following claims.

What is claimed is:

1. An operation method of a memory device, comprising:
writing first data to a plurality of memory cells corresponding to a plurality of word lines;
enabling a sense amplifier corresponding to the plurality of the memory cells;
setting second data in the sense amplifier, the second data having the opposite phase of the first data; and
sequentially enabling the plurality of word lines for a predetermined time while keeping the sense amplifier in an enabled state.

2. The operation method of claim 1, further comprising:
checking whether write recovery times (t R) of the memory cells are a pass or a fail, through read operations for the memory cells.

3. The operation method of claim 1, wherein the enabling of the plurality of word lines comprises activating one word line at a time.

4. The operation method of claim 1 wherein the enabling of the plurality of word lines comprises activating two or more of the plurality of the word lines at a time.

5. The operation method 1, wherein the setting o the second data is performed i n a state her of the word lines are disabled.

6. A memory device comprising:
a plurality of word lines;
a plurality of memory cells corresponding to the word lines;
a sense amplifier suitable for amplifying data of a memory cell corresponding to an enabled word line among the plurality of word lines, and maintaining an active state while being set with first data in a test mode; and
a test circuit suitable for controlling the plurality of word lines to be sequentially enabled for a predetermined time, in the test mode.

7. The memory device of claim 6, wherein second data are written to the plurality of memory cells before the entry of the test mode, the second data having the opposite phase of the first data.

8. The memory device of claim 7, wherein the plurality of word lines are enabled one at a time in a state where the sense amplifier is enabled in the test mode.

9. The memory device of claim 7, wherein two or more of the plurality of the word lines are enabled at a time in a state where the sense amplifier is enabled in the test mode.

10. The memory device of claim 7, further comprising:
a row circuit suitable for controlling the plurality of word lines,
wherein the row circuit controls the plurality of word lines in response to an external active command, an external precharge command, and/or an external row address applied from an external device in a normal mode, and controls the plurality of word lines in response to an internal active command, an internal precharge command, and/or an internal row address generated through the test circuit, in the test mode.

11. The memory device of claim 10, further comprising:
a sense amplifier control circuit suitable for controlling the sense amplifier,
wherein the sense amplifier control circuit enables and/or disables the sense amplifier in response to the external active command and the external precharge command in the normal mode, and controls the sense amplifier to maintain the active state in, the test mode.

12. The memory device of claim 11, further comprising:
a data control circuit suitable for controlling data exchange between the sense amplifier and a data bus,
wherein the data control circuit controls the data exchange between the sense amplifier and the data bus in response to an external read command, an external write command, and/or an external column address applied from an external device in the normal mode, and applies the second data to the sense amplifier in the test mode.

13. The memory device of claim 6, wherein in the test mode, all of the word lines are disabled at the point of time that the sense amplifier starts to be enabled.

14. An operation method of a memory device, comprising:
writing first data to a plurality of memory cells disposed at respective intersections between a plurality of word lines and a plurality of bit lines;
transmitting and loading second data to on he bit lines while disabling the word lines;
sequentially enabling the word lines for a predetermined time while loading the second data on the bit lines; and
checking whether the memory cells have first data or second data through read operations thereof.
